(19) United States
(12) Patent Application Publication
(10) Pub. No.: US 2017/0141734 A1
(43) Pub. Date: May 18, 2017

(54) CIRCUITS AND METHODS FOR CONTROLLING POWER AMPLIFIERS

(71) Applicant: SKYWORKS SOLUTIONS, INC., Woburn, MA (US)

(72) Inventor: Philip John LEHTOLA, Cedar Rapids, IA (US)

(21) Appl. No.: 15/353,452

(22) Filed: Nov. 16, 2016

Related U.S. Application Data
(60) Provisional application No. 62/255,600, filed on Nov. 16, 2015.

(51) Int. Cl. H03F 1/02; H04B 1/04; H03G 3/30; H03F 3/19; H03F 3/24

(52) U.S. Cl. CPC H03F 1/0205; H03F 3/19; H03F 3/245; H03G 3/3042; H04B 1/04; H03F 2200/451

(57) ABSTRACT

Circuits and methods for controlling power amplifiers. In some embodiments, a power amplification system can include a first amplification stage configured to operate with a first bias signal, and a second amplification stage configured operate with a second bias signal. The power amplification system can further include a control circuit coupled to the first amplification stage and the second amplification stage. The control circuit can be configured to generate the first bias signal based on the second bias signal. Such a first bias signal can result in the first stage having a gain profile that compensates for either or both of a gain expansion and gain compression of the second amplification stage.

### CROSS-REFERENCE TO RELATED APPLICATION(S)

This application claims priority to U.S. Provisional Application No. 62/255,600 filed Nov. 16, 2015, entitled METHOD AND APPARATUS FOR EXTENDING POWER AMPLIFIER OUTPUT LINEARITY AND EXTENDING BATTERY LIFE AND CONTROLLING ADJACENT CHANNEL LEAKAGE PERFORMANCE FOR MOBILE COMMUNICATION DEVICES, the disclosure of which is hereby expressly incorporated by reference herein in its respective entirety.

### BACKGROUND

Field

The present disclosure relates to circuits and methods for controlling power amplifiers, including AM-AM compensation of power amplifiers as they approach saturation.

Description of the Related Art

In some radio-frequency (RF) applications, open loop pre-distortion of an input signal to two-stage power amplifiers are utilized to compensate for gain expansion and compression near power amplifier saturation. Such designs typically monitor the input power and adjust the gain of a driver stage to compensate for the gain expansion and compression of a final stage. Such systems typically work well at a fixed temperature and output load condition.

While these types of pre-distortion systems may have many advantages in particular applications, they also have some drawbacks. For example, in many RF devices it is often not practical to fully anticipate the quantity and nature of process and/or thermal performance issues as well as the potential for and extent of load mismatches. These systems are not capable of addressing aftermarket variations in performance, especially if they vary more after extended use, consumer end product modification (e.g., utilizing certain phone cases which change the thermal characteristics or antenna efficiency of the phone) and/or misuses and abuse of an RF device such as a phone.

Accordingly, there exists a need for improved circuits, devices and/or methods for efficient control of power amplifiers, such as efficiently compensating for gain expansion and compression near the saturation of a power amplifier.

### SUMMARY

In accordance with some implementations, the present disclosure relates to a power amplification system that includes a first amplification stage configured to operate with a first bias signal, and a second amplification stage configured operate with a second bias signal. The power amplification system further includes a control circuit coupled to the first amplification stage and the second amplification stage. The control circuit is configured to generate the first bias signal based on the second bias signal. The first bias signal results in the first stage having a gain profile that compensates for either or both of a gain expansion and gain compression of the second amplification stage.

In some embodiments, the first amplification stage can be a driver stage configured to receive an un-amplified signal, and the second amplification stage can be a final output stage configured to generate an amplified signal as an output of the power amplification system. Each of the driver stage and the final output stage can include an amplifying transistor having a base, an emitter, and a collector, with the base being configured to receive a signal, and the collector being configured to output the signal. In some embodiments, the collector of the amplifying transistor of the driver stage can be coupled to the base of the amplifying transistor of the final output stage without any intermediate stage.

In some embodiments, the first bias signal can be a first bias current provided to the base of the amplifying transistor of the driver stage, and second bias signal can be a second bias current provided to the base of the amplifying transistor of the final output stage. Each of the first bias current and the second bias current can be provided to the respective base through a respective base bias network and a respective base resistance, with the base bias network being controlled by a respective reference current. The control circuit can include a current mirror having a first current branch providing an input current to the first base bias network to generate the first bias current, and a second current branch providing an input current to the second base bias network to generate the second bias current.

In some embodiments, the current mirror can be configured to have a current mirror transfer ratio of 1:M between the first current branch and the second current branch. The current mirror transfer ratio of 1:M can be selected such that the gain compression of the final output stage results in a rapid gain expansion of the driver stage. The quantity M can be greater than 1, 10, 20, 30, 40 or 50.

In some embodiments, the first base resistance for the driver stage can be a variable resistance. A resistance value of the variable resistance can be selected such that the gain expansion of the final output stage results in a gain compression of the driver stage.

In some embodiments, the first reference current for the first base bias network can be selected such that the gain expansion of the final output stage results in a gain compression of the driver stage.

In some teachings, the present disclosure relates to a method for amplifying a signal. The method includes amplifying a signal with a first amplification stage configured to operate with a first bias signal, and further amplifying the amplified signal from the first amplification stage with a second amplification stage configured operate with a second bias signal. The method further includes generating the first bias signal based on the second bias signal, with the first bias signal resulting in the first stage having a gain profile that compensates for either or both of a gain expansion and gain compression of the second amplification stage.

In some embodiments, the first bias signal can be a first bias current provided to a base of a first transistor of the first stage, and the second bias signal can be a second bias current provided to a base of a second transistor of the second stage. The generating of the first bias current can include controlling an amount of a current provided to a base resistance for the first transistor. The generating of the first bias current can include providing a current to a variable base resistance, such that the first bias current is determined by a resistance value of the variable base resistance.

In a number of implementations, the present disclosure relates to a wireless device that includes a transmitter configured to generate a signal, and a power amplification system configured to amplify the signal for transmission. The power amplification system includes a first amplification stage configured to operate with a first bias signal, and a second amplification stage configured operate with a second bias signal. The power amplification system further includes a control circuit coupled to the first amplification stage and the second amplification stage. The control circuit is configured to generate the first bias signal based on the second bias signal, with the first bias signal resulting in the first stage having a gain profile that compensates for either or both of a gain expansion and gain compression of the second amplification stage. The wireless device further includes an antenna in communication with the power amplification system and configured to facilitate the transmission of the amplified signal.

In some implementations, the present disclosure relates to a method of controlling power amplifier gain. The method includes providing a driver stage transistor for amplifying a signal, and providing a final stage transistor for further amplifying an output of the driver stage. The method further includes detecting a base current of the final stage transistor, and adjusting a base current of the driver stage transistor in response to the detected base current such that an expansion of a gain of the final stage transistor results in a compression in gain of the driver stage transistor.

In some embodiments, a base of the final stage transistor can be coupled to a collector of the driver stage transistor. The detecting of the base current of the final stage transistor can be performed by a current mirror implemented in a path between the base of the final stage transistor and the base of the driver stage transistor.

In some embodiments, the method can further include providing a variable base resistance for the driver stage transistor, and adjusting the variable base resistance to tune a mirroring characteristic between the base current of the final stage transistor and the base current of the driver stage transistor. The method can further include providing a base bias network between the current mirror and the base of the final stage transistor, and providing a reference current to the base bias network.

In some embodiments, the method can be free of any step of distorting the signal to compensate for gain compression of the final stage transistor. In some embodiments, the method can be free of any step of predetermining a distortion to be applied to the signal to compensate for gain compression of the final stage transistor.

In a number of implementations, the present disclosure relates to a system for power amplifier saturation detection and correction. The system includes an input for receiving a signal, a driver stage transistor, and a final stage transistor. The system further includes a current mirror configured to control a current through a terminal of the driver stage transistor based upon a current through a terminal of the final stage transistor so that a composite gain of the driver stage transistor and the final stage transistor has an improved linearity of gain as a function of power output when compared to either the driver stage transistor or the final stage transistor.

In some embodiments, the terminal of the driver stage transistor can be a base of the driver stage transistor. In some embodiments, the final stage transistor can be a bipolar transistor. In some embodiments, the current mirror can be configured to detect a current through a base of the final stage transistor.

In some embodiments, the system can further include a variable base resistance for the driver stage. The variable base resistance can be configured to provide a base resistance value for the driver stage to facilitate the improved linearity of gain.

According to a number of implementations, the present disclosure relates to a portable communication device that includes a transmitter configured to provide a signal, a driver stage transistor configured to receive the signal, and a final stage transistor coupled to the driver stage transistor. The device further includes a current mirror configured to control a current through a terminal of the driver stage transistor based upon a current through a terminal of the final stage transistor so that a composite gain of the driver stage transistor and the final stage transistor has improved linearity of gain as a function of power output when compared to either the driver stage transistor or the final stage transistor.

In some embodiments, the current mirror can be configured to permit at least one of lower power consumption for operation of portable communication device and improvement in adjacent channel leakage ratio performance.

For purposes of summarizing the disclosure, certain aspects, advantages and novel features of the inventions have been described herein. It is to be understood that not necessarily all such advantages may be achieved in accordance with any particular embodiment of the invention. Thus, the invention may be embodied or carried out in a manner that achieves or optimizes one advantage or group of advantages as taught herein without necessarily achieving other advantages as may be taught or suggested herein.

### BRIEF DESCRIPTION OF THE DRAWINGS

FIG. 1 shows a block diagram of a power amplifier (PA) system having one or more features as described herein.

FIG. 2 shows a block diagram of an example wireless device having the power amplifier system of FIG. 1.

FIG. 3 depicts a more detailed example of the power amplifier system as shown in FIG. 2.

FIG. 4 shows example gain profile plots of output and driver stages of a Class E power amplifier.

FIG. 5 shows plots of a normalized gain per stage and a composite normalized gain for a combination of stages of the power amplifier having one or more features as described herein.

FIG. 6 shows a process that can be implemented to control an amplifier.

FIG. 7 shows a process that can be implemented as a more specific example of the process of FIG. 6.

### DETAILED DESCRIPTION OF SOME EMBODIMENTS

The headings provided herein, if any, are for convenience only and do not necessarily affect the scope or meaning of the claimed invention.

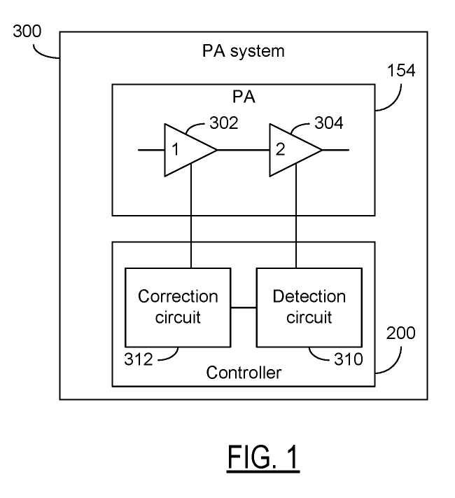

FIG. 1 shows a block diagram of a power amplifier (PA) system 300 having one or more desirable features as described herein. In some embodiments, such a PA system can include a power amplifier 154 and a controller 200. The power amplifier 154 can include a plurality of amplification stages. For example, a first stage 302 can be a driver stage, and a second stage 304 can be a final output stage. It will be understood that there may or may not be an intermediate stage between the first stage 302 and the second stage 304.

In some embodiments, an operating parameter of one amplification stage can be detected, and such an operating parameter can be utilized to generate a correction signal to adjust operation of another amplification stage. Such a cooperation of detection and correction between the two amplification stages can provide a desirable performance improvement of the power amplifier 154. For example, an operating parameter of the final output stage 304 can be detected, and such an operating parameter can be utilized to generate a correction control signal that adjusts operation of the driver stage 302. More specific examples related to such a detection/correction configuration are described herein in greater detail.

In some embodiments, and as shown in the example of FIG. 1, the foregoing detection of the operating parameter of the final output stage 304 can be achieved by a detection circuit 310. Such a detection circuit can be a part of the controller 200 or be under the control of the controller 200. The controller 200 can also include or control a correction circuit 312 that is in communication with the detection circuit 310. Such a correction circuit can be configured to provide at least some control of the driver stage 302, including adjustment of operation of the driver stage 302 based on the detected operating parameter of the final output stage 304.

In some embodiments the PA system 300 can be implemented in one or more devices. For example, substantially all of the power amplifier 154 and the controller 200 can be implemented in a packaged module such as a radio-frequency (RF) module. In another example, the PA system 300 can be configured such that the power amplifier 154 is implemented in one device (e.g., a semiconductor die or a packaged module) and the controller 200 is implemented in another device (e.g., a semiconductor die or a packaged module). Other configurations of the PA system 300 can also be implemented.

In the foregoing example where the PA system 300 is implemented in a single packaged module, the power amplifier 154 and the controller 200 can be implemented on one or more semiconductor die. For example, substantially all of the power amplifier 154 and the controller 200 can be implemented on a single semiconductor die. In another example, the power amplifier 154 can be implemented on a first semiconductor die, and the controller 200 can be implemented on a second semiconductor die.

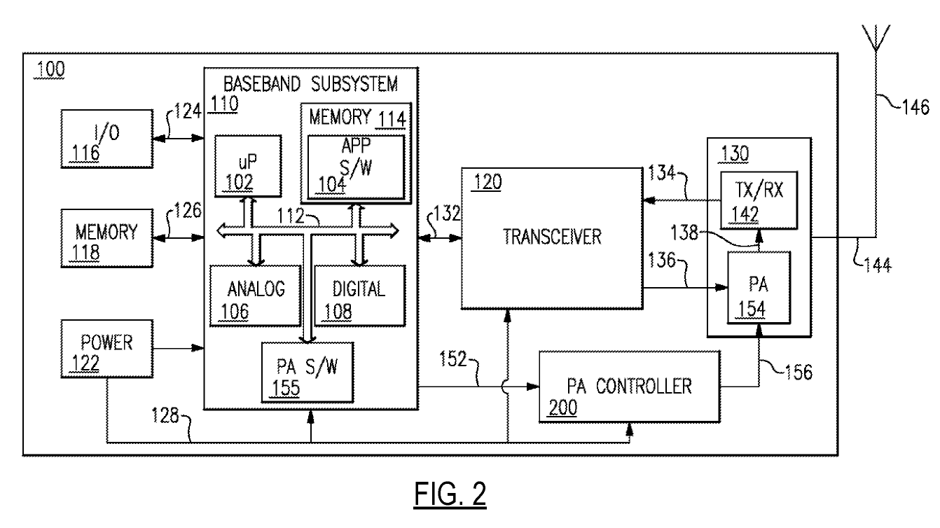

FIG. 2 depicts a wireless device such as a portable communication device 100. In some embodiments, the portable communication device 100 can be, for example, a portable cellular telephone, a smart-phone, a hand-held wireless device with or without phone functionality, a wireless tablet, etc.

In some embodiments, the PA system 300 of FIG. 1 can be configured to provide gain compression compensation, and such a desirable functionality can be implemented in any device having a power amplifier. The portable communication device 100 of FIG. 2 is an example of such a device with a power amplifier.

It is noted that the portable communication device 100 depicted in FIG. 2 is intended to be a simplified example of a cellular telephone and to show one of a number of possible applications in which the gain compression compensation can be implemented. One having ordinary skill in the art will understand the operation of a portable cellular telephone, and, as such, implementation details are not shown herein.

Referring to FIG. 2, the portable communication device 100 can include a subsystem 110, a transceiver 120, a front-end module (FEM) 130 and a power amplifier controller 200. Although not shown, the transceiver 120 typically includes modulation and up-conversion circuitry for preparing a signal for amplification and transmission. The transceiver 120 can also include filtering and down-conversion circuitry for receiving and down-converting an RF signal to an information signal. Various details associated with operation of the transceiver 120 are generally known to those skilled in the art.

Referring to FIG. 2, the subsystem 110 typically includes a processor 102, which can be a general purpose or special purpose microprocessor, memory 114, application software 104, analog circuit elements 106, digital circuit elements 108, and power amplifier software 155, coupled over a system bus 112. The system bus 112 can include physical and logical connections to couple the above-described elements together and enable their inter-operability.

An input/output (I/O) element 116 can be provided and be connected to the subsystem 110 over connection 124. A memory element 118 can be provided and be coupled to the subsystem 110 over connection 126. A power source 122 can be provided and be connected to the subsystem 110, transceiver 120 and power amplifier controller 200 over connection 128.

In some embodiments, the I/O element 116 can include, for example, a microphone, a keypad, a speaker, a pointing device, user interface control elements, and any other devices or system that allow a user to provide input commands and receive outputs from the portable communication device 100.

In some embodiments, the memory 118 can be any type of volatile memory, non-volatile memory, or a combination thereof, and in some embodiments, can include flash memory. The memory element 118 can be permanently installed in the portable communication device 100, or can be a removable memory element, such as a removable memory card, or a combination of fixed and removable memory.

In some embodiments, the power source 122 can be, for example, a battery, or other rechargeable power source, or can be an adaptor that converts AC power to the correct voltage used by the portable communication device 100.

In some embodiments, the processor 102 can be any processor that executes the application software 104 to control the operation and functionality of the portable communication device 100. The memory 114 can be volatile memory, non-volatile memory, or a combination thereof, and in some embodiments, can be non-volatile memory that stores the application software 104. If portions of functionality for gate voltage biasing are implemented in software, then the subsystem 110 also includes power amplifier software 155 that can be stored in the memory 114 and executed by the microprocessor 102, or by another processor, which may cooperate with control logic to control the operation of at least portions of the power amplifier controller 200 as described herein.

In some embodiments, the analog circuitry 106 and the digital circuitry 108 can include functionalities such as signal processing, signal conversion, and logic that convert an input signal provided by the I/O element 116 to an information signal that is to be transmitted. Similarly, the analog circuitry 106 and the digital circuitry 108 can include functionalities such as signal processing, signal conversion, and logic that convert a received signal provided by the transceiver 120 to an information signal that contains recovered information. The digital circuitry 108 can include, for example, a digital signal processor (DSP), a field programmable gate array (FPGA), or any other processing device. Because the subsystem 110 includes both analog and digital elements, it is sometimes referred to as a mixed signal device (MSD).

In some embodiments, the front-end module 130 can include a transmit/receive (TX/RX) switch 142 and a power amplifier 154. The front-end module 130 can also include a duplexer, a diplexer, or any other physical or logical device or circuitry that separates a transmit signal and a receive signal. Depending on the implementation of the portable communication device 100, the front-end module 130 may be implemented to provide half-duplex or full-duplex functionality. A transmit signal provided by the transceiver 120 over connection 136 can be directed to the power amplifier 154. The output of the power amplifier 154 can be provided over connection 138 to the TX/RX switch 142, and then to an antenna 146 over connection 144.

In some embodiments, the power amplifier controller 200 can include circuitry and logic that controls the power output of the power amplifier 154. In some embodiments, the power amplifier controller 200 can include a current mirror and associated circuitry. Examples related to such current mirror and associated circuitry are described herein in greater detail.

A signal received by the antenna 146 can be provided over connection 144 to the TX/RX switch 142, which provides the received signal over connection 134 to the transceiver 120. The received signal can then be provided over connection 132 to the subsystem 110 for further processing.

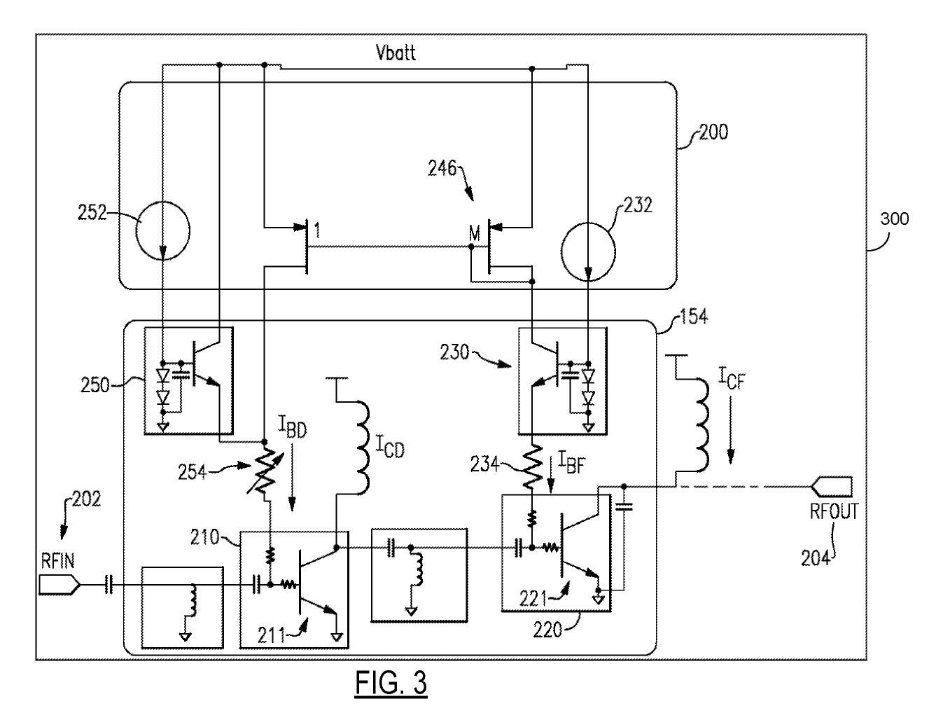

FIG. 3 depicts a more detailed example of the power amplifier system as shown in FIGS. 1 and 2. Referring to FIG. 3, a two-stage Class E power amplifier circuit 154 can be implemented with AM-AM compensation, and an associated PA controller 200 can be configured to facilitate such compensation. Although the example power amplifier circuit 154 is described in the context of Class E configuration, it will be understood that one or more features of the present disclosure can also be implemented with other classes of power amplifiers.

In the example of FIG. 3, an unamplified RF signal can be provided at an input 202 (RFIN) and an amplified RF signal can be provided at an output 204 (RFOUT). The two stages of the power amplifier circuit 154 include a driver stage 210 and a final output stage 220. More particularly, the unamplified RF signal from the input 202 is shown to be provided to a base of a driver stage transistor 211, and a partially amplified RF signal is shown to be provided at a collector of the transistor 211. Such a partially amplified RF signal is shown to be provided to a base of a final output stage transistor 221, and the amplified RF signal is shown to be provided at a collector of the transistor 221. The collector of the transistor 221 is shown to be coupled to the output 204.

In the example of FIG. 3, the transistor 221 of the final output stage 220 is shown to be biased at its base through a final stage base bias network 230 and a final stage base resistance 234. The transistor 211 of the driver stage 210 is shown to be biased at its base through a driver stage base bias network 250 and a variable driver stage base resistance 254. The final stage base bias network 230 and the driver stage base bias network 250 are shown to be coupled to a current mirror 246 of a PA controller 200.

In some operating situations, to avoid saturated output power of the Class E power amplifier circuit 154 being limited by the driver stage 210, it is necessary or desirable to have the compression point of the driver stage 210 be higher (e.g., >3 dB) than that of the final output stage 220. In the example of FIG. 3, the final output stage 220 is preferably a Class E amplifier which has well known and desired bandwidth characteristics (e.g., generally very linear AM-AM at low output power but with relatively wide expansion and compression of gain near amplifier saturation).

Again, it will be understood that while Class E amplifiers may be favored for certain applications, other classes of amplifiers and completely different types of amplifiers could benefit from one or more features of the present disclosure as well. Accordingly, some or all features of the present disclosure and various examples described herein are not intended to be limited to Class E amplifiers.

In the context of Class E amplification configuration, it is noted that such a configuration includes a number of desirable characteristics, including, for example, bandwidth, simple implementation of harmonic termination network, and high collector efficiency. For an output stage of such a Class E configuration, it is noted that the stage's AM-AM characteristics can be effectively determined by Class E operation of the amplifier. For example, at low power operation, a high base current can be achieved by a low impedance bias network to provide a gain expansion. At high power operation, saturated V_{CE} waveform can result in a beta roll-off characteristic of the gain profile, followed by a gain compression.

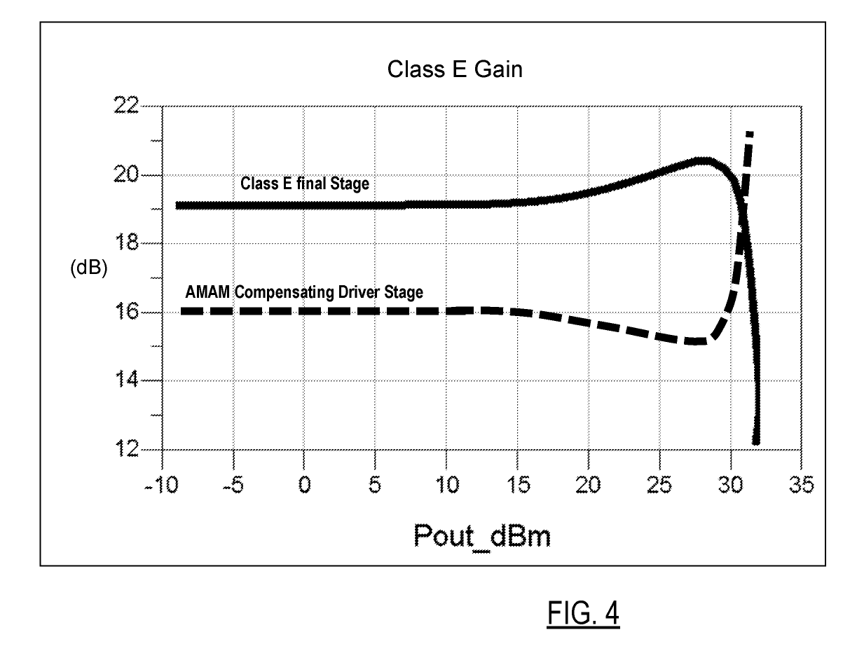

The foregoing gain characteristics of the Class E output stage (e.g., 220 in FIG. 3) are depicted in a solid-line gain plot of FIG. 4. In such a gain plot, one can see that as the output power is increased, gain expansion occurs to a roll-off point, followed by a sharp gain compression.

In some embodiments, a power amplifier system having one or more features as described herein can be configured such that the driver stage is configured and/or operated such that its gain profile generally mirrors the gain profile of the output stage. In the example of FIG. 4, such a gain profile of the driver stage is depicted by a dashed-line plot. More particularly, the driver stage gain profile is shown to include a compression trend where the expansion occurs in the output stage, and a rapid expansion where the sharp compression occurs in the output stage.

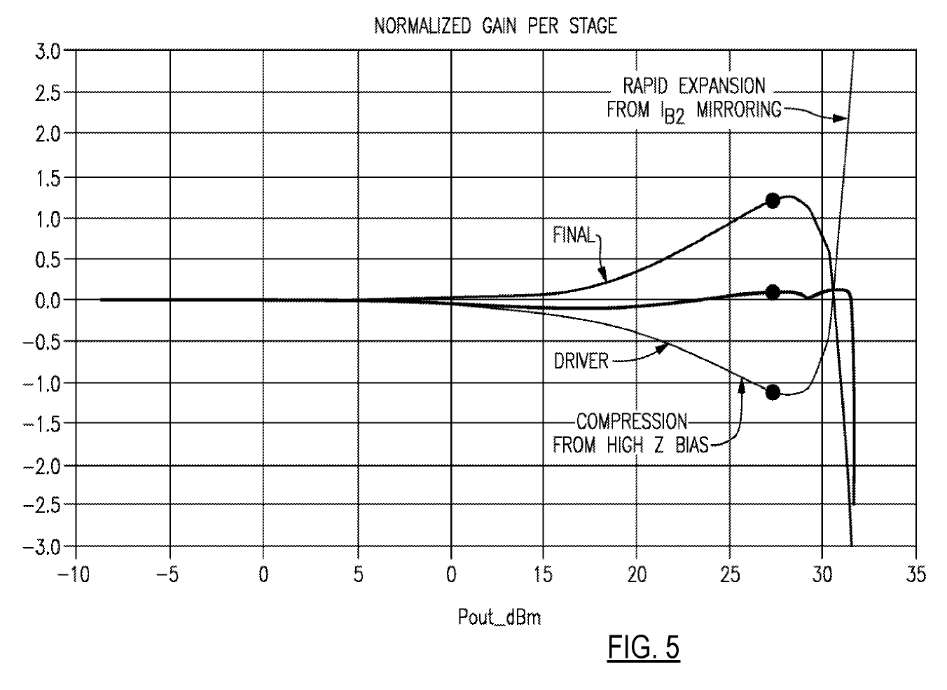

In some embodiments, the driver stage can be configured and/or operated such that the gain of the amplifier as a whole has a desirable profile. For example, such a desirable gain profile of the amplifier can be approximately flat up to the amplifier's saturation point. An example of such a desirable gain profile of the amplifier is described herein in reference to FIG. 5.

In the example of FIG. 4, it is noted that the compression trend of the driver stage can compensate for the expansion of the output stage in the power range lower than the roll-off point. Similarly, the rapid expansion of the driver stage can compensate for the sharp compression of the output stage in the power range higher than the roll-off point.

It is noted that the gains provided by the driver stage and the output stage may or may not be the same. Assuming that such gains of the driver stage and the output stage are different (as in the example of FIG. 4), the generally mirrored profiles of the driver stage and the output stage may or may not have the same expansion and compression magnitudes. For example, the difference in gain between the roll-off point and the low-power flat region of the output stage may or may not be the same as the difference in gain between the roll-off point and the low-power flat region of the driver stage. In some embodiments, the driver stage can be configured and/or operated such that its gain profile, when combined with the gain profile of the output stage, results in the power amplifier's gain profile to have a desired shape (e.g., approximately flat up to saturation). It is noted that the example of FIG. 3 allows the driver stage to be configured and/or operated in such a manner.

Referring to the example of FIG. 3, it is noted that when the final output stage transistor 221 begins to draw substantial base current I_{BF} through the final output stage base resistance 234, such a substantial base current signals the beginning of compression of the final output stage gain because the transistor's beta will degrade when the amplifier saturates. This base current I_{BF} is provided through the final output stage base bias network 230 and is sensed at the current mirror 246.

In some embodiments, the current mirror 246 functionality could be implemented in various manners, including with an aid of an external controller die which might be disposed in the PA controller 200 (e.g., as in the example of FIG. 2). In some embodiments, mirror ratio of the current mirror 246 can be adjusted to fine tune the expansion of the driver stage 210 gain to oppose the compression of the final output stage 220 gain.

In the example of FIG. 3, the current mirror 246 is shown to include a diode connected PFET or PNP in series with the final output stage base current to provide a reference voltage for the current mirror 246. The current mirror 246 can further include a PFET or PNP with its gate/base connected to the diode connected PFET or PNP, source/emitter connected to a supply voltage (e.g., Vbatt), and drain/collector coupled to the base of the driver stage transistor 211. The current flowing into the base of the driver stage transistor 211 can be a fixed ratio of the current flowing into the base of the final output stage transistor, determined by the mirror ratio of the current mirror 246. Such a mirror ratio can be scaled by increasing/decreasing the size of the reference diode or the mirror transistor.

In the example of FIG. 3, the current mirror 246 is shown to provide a base bias current I_{BD} for the driver stage 210 through the variable driver stage base resistance 254. In some embodiments, such a base bias current can be provided to result in diametrically opposed gain compression and expansion characteristics of the driver stage 210 and the final output stage 220 combining to provide an ideal or a near ideal linear power amplifier performance.

FIG. 3 shows that in some embodiments, the controller 200 can include a reference current source 232 configured to provide a reference current I_{Ref2} to the final output stage base bias network 230. The controller 200 can also include a reference current source 252 configured to provide a reference current I_{Ref1} to the driver stage base bias network 250.

FIG. 3 also shows that in some embodiments, the current mirror 246 can be configured to provide a current mirror transfer ratio of M:1 between the diode connected PFET or PNP associated with the final output stage 220 and the PFET or PNP associated with the driver stage 210.

In some embodiments, the expansion characteristic of the final output stage 220 can be set by a combination of the reference current I_{Ref2} and the base current I_{BF} for the final output stage 220. For such an expansion characteristic of the final output stage 220, either or both of the reference current I_{Ref1} and the base current I_{BD} for the driver stage 210 can be set or adjusted to provide a driver stage compression profile to compensate for the expansion characteristic of the final output stage 220. As described herein, such compensation of the expansion characteristic of the final output stage 220 by the compression of the driver stage 210 can be implemented at low power (e.g., below the roll-off point).

In some embodiments, the current mirror transfer ratio M:1 can be selected to provide a desired amount of driver stage expansion to compensate for the final output stage compression leading up to the saturation point. As described herein, such a current mirror transfer ratio M:1 can be selected by, for example, increasing/decreasing the size of the reference diode or the mirror transistor.

Now referring to FIG. 5, there is shown graphical representation of normalized gain for each of the driver stage 210 and the final output stage 220, and a composite line representing the gain of the two stage Class E power amplifier circuit 154 of FIG. 3. It is noted that for the final output stage 220, the gain curve displays an expansion before a sharp compression to saturation. As described herein, operation of the driver stage 210 be configured to counter the foregoing gain profile of the final output stage 220.

In the example of FIG. 5, the current mirror transfer ratio of M:1 between the diode connected PFET or PNP associated with the final output stage 220 and the PFET or PNP associated with the driver stage 210 is selected such that M=50. It will be understood that other values of M can also be implemented. For example, in some embodiments, M can be greater than 1, 10, 20, 30, 40 or 50.

In some embodiments, the portable communication device 100 of FIGS. 2 and 3 may function as follows. The final output stage transistor 221 with the aid of the AM-AM compensation system as described herein is able to operate at a higher output power before substantial compression occurs, and therefore operate with higher efficiency and consume less battery power. In an alternative, the final output stage transistor 221 is able to operate in such a manner as to improve the adjacent channel leakage ratio (ACLR) and thereby provide for improved quality of performance for nearby phones. It is noted that a trade-off of battery life vs ACLR improvement could result in some situations; however, a desirable combination of battery life and ACLR performance can be achieved.

It is noted that specific implementation of one or more features of the present disclosure can vary depending upon the particular application. For example, a cellphone may utilize different transistors than a local area network (LAN) transmitter. Even among cellphones, differences in frequency bands across different cellphone carriers can result in different operating parameter values as well as other variations.

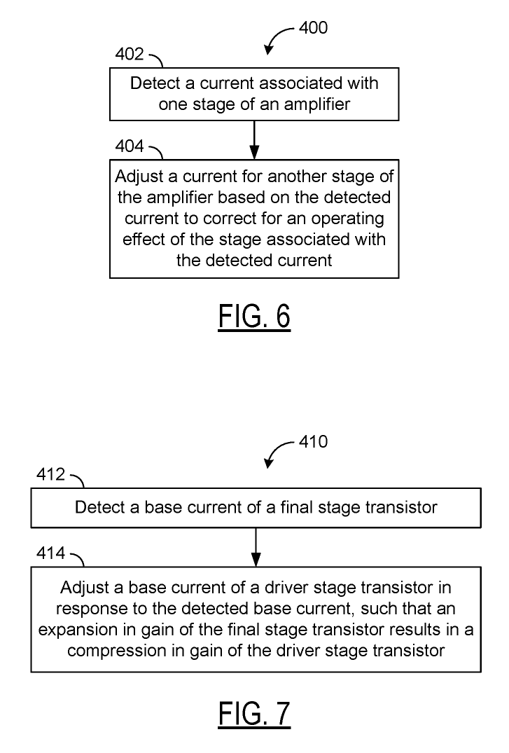

FIG. 6 shows a process 400 that can be implemented to correct for an operating effect of one stage by adjusting a current provided to another stage of an amplifier. In block 402, a current associated with one stage of an amplifier can be detected. In block 404, a current provided to another stage of the amplifier can be adjusted based on the detected current. Such a current provided to the other stage can be configured to correct for an operating effect of the stage associated with the detected current.

In various examples described herein, the stage associated with the detected current is a final output stage of a power amplifier, and the other stage is a driver stage. In such a context, FIG. 7 shows a process 410 that can be a more specific example of the process 400 of FIG. 6. In block 412, a base current of a final output stage transistor can be detected. In block 414, a base current provided to a driver stage can be adjusted in response to the detected base current, such that an expansion in gain of the final output stage transistor results in a compression in gain of the driver stage transistor.

It is noted that the process 410 of FIG. 7 assumes that the expansion characteristics of the driver stage transistor is set by the current mirror ratio as described herein to compensate for the compression of the final output stage transistor. However, in situations where the current mirror can be adjusted (e.g., with an assembly of switchable transistor devices), or other methods can be implemented to controllably provide similar functionality, the process 410 can include a step where an adjustment is made to the operation of the driver stage transistor to provide an expansion to compensate for the compression of the final output stage transistor.

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Description using the singular or plural number may also include the plural or singular number respectively. The word “or” in reference to a list of two or more items, that word covers all of the following interpretations of the word: any of the items in the list, all of the items in the list, and any combination of the items in the list.

The above detailed description of embodiments of the invention is not intended to be exhaustive or to limit the invention to the precise form disclosed above. While specific embodiments of, and examples for, the invention are described above for illustrative purposes, various equivalent modifications are possible within the scope of the invention, as those skilled in the relevant art will recognize. For example, while processes or blocks are presented in a given order, alternative embodiments may perform routines having steps, or employ systems having blocks, in a different order, and some processes or blocks may be deleted, moved, added, subdivided, combined, and/or modified. Each of these processes or blocks may be implemented in a variety of different ways. Also, while processes or blocks are at times shown as being performed in series, these processes or blocks may instead be performed in parallel, or may be performed at different times.

The teachings of the invention provided herein can be applied to other systems, not necessarily the system described above. The elements and acts of the various embodiments described above can be combined to provide further embodiments.

While some embodiments of the inventions have been described, these embodiments have been presented by way of example only, and are not intended to limit the scope of the disclosure. Indeed, the novel methods and systems described herein may be embodied in a variety of other forms; furthermore, various omissions, substitutions and changes in the form of the methods and systems described herein may be made without departing from the spirit of the disclosure. The accompanying claims and their equivalents are intended to cover such forms or modifications as would fall within the scope and spirit of the disclosure.

1. A power amplification system comprising:
a first amplification stage configured to operate with a first bias signal;
a second amplification stage configured operate with a second bias signal; and
a control circuit coupled to the first amplification stage and the second amplification stage, the control circuit configured to generate the first bias signal based on the second bias signal, the first bias signal resulting in the first stage having a gain profile that compensates for either or both of a gain expansion and gain compression of the second amplification stage.

2. The power amplification system of claim 1 wherein the first amplification stage is a driver stage configured to receive an un-amplified signal.

3. The power amplification system of claim 2 wherein the second amplification stage is a final output stage configured to generate an amplified signal as an output of the power amplification system.

4. The power amplification system of claim 3 wherein each of the driver stage and the final output stage includes an amplifying transistor having a base, an emitter, and a collector, the base configured to receive a signal, and the collector configured to output the signal.

5. The power amplification system of claim 4 wherein the collector of the amplifying transistor of the driver stage is coupled to the base of the amplifying transistor of the final output stage without any intermediate stage.

6. The power amplification system of claim 4 wherein the first bias signal is a first bias current provided to the base of the amplifying transistor of the driver stage, and second bias signal is a second bias current provided to the base of the amplifying transistor of the final output stage.

7. The power amplification system of claim 6 wherein each of the first bias current and the second bias current is provided to the respective base through a respective base bias network and a respective base resistance, the base bias network being controlled by a respective reference current.

8. The power amplification system of claim 7 wherein the control circuit includes a current mirror having a first current branch providing an input current to the first base bias network to generate the first bias current, and a second current branch providing an input current to the second base bias network to generate the second bias current.

9. The power amplification system of claim 8 wherein the current mirror is configured to have a current mirror transfer ratio of 1:M between the first current branch and the second current branch.

10. The power amplification system of claim 9 wherein the current mirror transfer ratio of 1:M is selected such that the gain compression of the final output stage results in a rapid gain expansion of the driver stage.

11. The power amplification system of claim 10 wherein the quantity M is greater than 1.

12. The power amplification system of claim 11 wherein the quantity M is greater than 10, 20, 30 or 40.

13. The power amplification system of claim 8 wherein the first base resistance for the driver stage is a variable resistance.

14. The power amplification system of claim 13 wherein a resistance value of the variable resistance is selected such that the gain expansion of the final output stage results in a gain compression of the driver stage.

15. The power amplification system of claim 8 wherein the first reference current for the first base bias network is selected such that the gain expansion of the final output stage results in a gain compression of the driver stage.

16. A method for amplifying a signal, the method comprising:
amplifying a signal with a first amplification stage configured to operate with a first bias signal;
further amplifying the amplified signal from the first amplification stage with a second amplification stage configured operate with a second bias signal; and
generating the first bias signal based on the second bias signal, the first bias signal resulting in the first stage having a gain profile that compensates for either or both of a gain expansion and gain compression of the second amplification stage.

17. The method of claim 16 wherein the first bias signal is a first bias current provided to a base of a first transistor of the first stage, and the second bias signal is a second bias current provided to a base of a second transistor of the second stage.

18. The method of claim 17 wherein the generating of the first bias current includes controlling an amount of a current provided to a base resistance for the first transistor.

19. The method of claim 17 wherein the generating of the first bias current includes providing a current to a variable base resistance, such that the first bias current is determined by a resistance value of the variable base resistance.

20. A wireless device comprising:
a transmitter configured to generate a signal;
a power amplification system configured to amplify the signal for transmission, the power amplification system including a first amplification stage configured to operate with a first bias signal, and a second amplification stage configured operate with a second bias signal, the power amplification system further including a control circuit coupled to the first amplification stage and the second amplification stage, the control circuit configured to generate the first bias signal based on the second bias signal, the first bias signal resulting in the first stage having a gain profile that compensates for either or both of a gain expansion and gain compression of the second amplification stage; and
an antenna in communication with the power amplification system and configured to facilitate the transmission of the amplified signal.

21-35. (canceled)
